(19) United States
(12) Patent Application Publication
(10) Pub. No.: US 2025/0081745 A1
(43) Pub. Date: Mar. 6, 2025

(54) DISPLAY PANEL AND MANUFACTURING METHOD THEREOF

(71) Applicant: SAMSUNG DISPLAY CO., LTD., YONGIN-SI (KR)

(72) Inventor: CHUN GI YOU, Yongin-si (KR)

(21) Appl. No.: 18/664,692

(22) Filed: May 15, 2024

(30) Foreign Application Priority Data
Aug. 29, 2023 (KR) 10-2023-0113996

(51) Int. Cl. H10K 59/122; H10K 59/12; H10K 59/131; H10K 71/60

(52) U.S. Cl. CPC H10K 59/122; H10K 59/1201; H10K 59/131; H10K 71/60

(57) ABSTRACT

A method of manufacturing a display panel includes forming, on a substrate, a pixel circuit layer including a sub-pixel circuit of each of a plurality of sub-pixels; forming a first electrode of a light emitting element on the pixel circuit layer, the first electrode of the light emitting element electrically connected to the sub-pixel circuit; forming a pixel defining layer on the first electrode of the light emitting element; and forming a light emitting structure of the light emitting element on the pixel defining layer. In addition, the method includes forming a hole at a boundary area between the plurality of sub-pixels. The hole may be formed using a wire of a hole generator. In addition, the method may include forming a second electrode of the light emitting element on the light emitting structure.

### CROSS-REFERENCE TO RELATED APPLICATION

The present application claims priority under 35 U.S.C. § 119(a) to Korean patent application No. 10-2023-0113996, filed on Aug. 29, 2023, in the Korean Intellectual Property Office, the entire disclosure of which is incorporated by reference herein.

### BACKGROUND

### 1. Technical Field

One or more embodiments described herein relate to a display panel and a manufacturing method thereof.

### 2. Related Art

The importance of display devices has increased as information technologies evolve. Examples of display devices include liquid crystal display devices, organic light emitting display devices, and an inorganic light emitting display devices.

In a super-resolution display, the distance between sub-pixels is narrow. As a result, leakage current (or lateral leakage phenomenon) may occur between adjacent sub-pixels through a commonly provided light emitting structure. The sub-pixels, therefore, may not emit light with a desired luminance, which adversely affects display quality.

### SUMMARY

Embodiments provide a display panel and a manufacturing method thereof, which can reduce influence of a leakage current migrating between pixels, or sub-pixels, that can deteriorate the quality of images displayed by the display panel.

In accordance with an aspect of the present disclosure, there is provided a method of manufacturing a display panel, the method including: forming, on a substrate, a pixel circuit layer including a sub-pixel circuit of each of a plurality of sub-pixels; forming a first electrode of a light emitting element on the pixel circuit layer, wherein the first electrode of the light emitting element is electrically connected to the sub-pixel circuit; forming a pixel defining layer on the first electrode of the light emitting element; forming a light emitting structure of the light emitting element on the pixel defining layer; forming a hole in a boundary area between adjacent ones of the plurality of sub-pixels, wherein the hole is formed using a wire of a hole generator; and forming a second electrode of the light emitting element on the light emitting structure.

Forming the hole may include: applying a high-potential voltage to a first end of the wire; and applying a low-potential voltage to a second end of the wire.

The plurality of sub-pixels may be arranged side-by-side in a first direction and a second direction intersecting the first direction in the display panel. Forming the hole may include: forming a first hole between the plurality of sub-pixels arranged side-by-side in the first direction; and forming a second hole between the plurality of sub-pixels arranged side-by-side in the second direction.

The light emitting structure may include a first light emitting area, a charge generation layer stacked in a third direction on the first light emitting unit, and a second light emitting area stacked in the third direction on the charge generation layer. In forming the hole, the light emitting structure may be removed to a predetermined depth by the wire.

In forming the hole, the second light emitting area and the charge generation layer may be sequentially removed.

In forming the hole, at least a portion of the first light emitting area may be further removed.

In forming the hole, the pixel defining layer may be exposed.

In forming the hole, a width of the hole may be formed less than a width of a top surface of the pixel defining layer.

In forming the hole, at least a portion of the first light emitting area may be exposed.

In forming the hole, a width of the hole may be formed less than a width of a top surface of the pixel defining layer.

In forming the hole, a width of the hole may be formed to be greater than a width of a top surface of the pixel defining layer.

The hole and the first electrode of the light emitting element may be located while overlapping with each other in the third direction.

The wire may include silver and have a width of 200 nm.

In the forming of the hole, any one of the substrate and the hole generator may be rotated by 90 degrees.

In accordance with another aspect of the present disclosure, there is provided a display panel including: a substrate having a plurality of sub-pixels disposed thereon; a pixel circuit layer disposed on the substrate, the pixel circuit layer including a sub-pixel circuit of each of the plurality of sub-pixels; and a light emitting element layer disposed on the pixel circuit layer, the light emitting element layer including a plurality of light emitting elements, each including a first electrode, a light emitting structure, and a second electrode, the light emitting element layer having a hole at least a portion of the light emitting structure in a boundary area between the plurality of sub-pixels. The hole may be formed using the wire of a hole generator.

The plurality of sub-pixels may be arranged side-by-side in a first direction and a second direction intersecting the first direction. The hole may be located between the plurality of sub-pixels arranged side-by-side in the first direction and between the plurality of sub-pixels arranged side-by-side in the second direction.

The light emitting structure may include: a first light emitting unit including a first light emitting layer; a charge generation layer stacked in a third direction on the first light emitting unit; and a second light emitting unit including a second light emitting layer, the second light emitting unit being stacked in the third direction on the charge generation layer. The hole may be located in an area in which the second light emitting unit and the charge generation layer are removed.

The hole may be located in an area in which the first light emitting unit is further removed.

The hole and the first electrode of the light emitting element may overlap with each other in the third direction.

In accordance with one or more embodiments, a display panel includes a first sub-pixel including a first electrode; a second sub-pixel including a second electrode adjacent to the first electrode; and a light emitting structure disposed on the first electrode and the second electrode, wherein the light emitting structure includes a hole disposed at a location between the first sub-pixel and the second sub-pixel, the hole extending to a depth that removes a charge generation layer between a stacked arrangement of different light emitting areas of at least one of the first sub-pixel and the second sub-pixel.

The display panel may include a pixel defining layer commonly included in the first sub-pixel and the second sub-pixel. The depth of the hole may be less than a distance between a top surface of the first electrode and a top surface of the light emitting structure. The hole may overlap the pixel defining layer. The hole may have a width that is less than a width between the first electrode and the second electrode.

The hole may have a width that is less than a width between the first electrode and the second electrode. The hole may have a width greater than a width between the first electrode and the second electrode. The hole may overlap respective portions of the first electrode and the second electrode. The depth of the hole may be less than a distance between a top surface of the first electrode and a top surface of the light emitting structure.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a system block diagram of a display device in accordance with embodiments of the present disclosure.

FIG. 2 is a block diagram illustrating an embodiment of any one of sub-pixels shown in FIG. 1.

FIG. 3 is a plan view illustrating an embodiment of a display panel shown in FIG. 1.

FIG. 4 is an exploded perspective view illustrating a portion of the display panel shown in FIG. 3 according to an embodiment.

FIG. 5 is a plan view illustrating an embodiment of any one of pixels shown in FIG. 4.

FIG. 6 is a sectional view illustrating a light emitting structure including a hole in accordance with an embodiment of the present disclosure, taken along line I-I′ of the pixel shown in FIG. 5.

FIG. 7 is a sectional view illustrating a light emitting structure including a hole in accordance with an embodiment of the present disclosure, taken along line I-I′ of the pixel shown in FIG. 5.

FIG. 8 is a sectional view illustrating a light emitting structure including a hole in accordance with an embodiment of the present disclosure, taken along line I-I′ of the pixel shown in FIG. 5.

FIG. 9 is a sectional view illustrating an embodiment of a light emitting structure in accordance with embodiments of the present disclosure.

FIG. 10 is a sectional view illustrating an embodiment in which the light emitting structure shown in FIG. 9 includes a hole.

FIG. 11 is a sectional view illustrating an embodiment in which the light emitting structure shown in FIG. 9 includes a hole.

FIG. 12 is a sectional view illustrating an embodiment of a light emitting structure in accordance with embodiments of the present disclosure.

FIG. 13 is a sectional view illustrating an embodiment in which the light emitting structure shown in FIG. 12 includes a hole.

FIG. 14 is a sectional view illustrating another embodiment in which the light emitting structure shown in FIG. 12 includes a hole.

FIG. 15 is a plan view illustrating a display panel in which a hole is generated in one direction by a hole generator in accordance with embodiments of the present disclosure.

FIG. 16 is a plan view illustrating the display panel in which a hole is generated in another direction by the hole generator in accordance with embodiments of the present disclosure.

FIG. 17 is a plan view illustrating the display panel in which a hole is formed according to an embodiment.

FIG. 18 is a system diagram of a hole generator in accordance with embodiments of the present disclosure.

FIG. 19 is a diagram illustrating an embodiment of a display system in accordance with embodiments of the present disclosure.

FIG. 20 is a perspective view illustrating an application example of the display system shown in FIG. 19.

FIG. 21 is a view illustrating an embodiment of a head-mounted display device worn by a user.

### DETAILED DESCRIPTION

Hereinafter, exemplary embodiments are described in detail with reference to the accompanying drawings so that those skilled in the art may easily practice the present disclosure. The present disclosure may be implemented in various different forms and is not limited to the exemplary embodiments described in the present specification.

A part irrelevant to the description will be omitted to clearly describe the present disclosure, and the same or similar constituent elements will be designated by the same reference numerals throughout the specification. Therefore, the same reference numerals may be used in different drawings to identify the same or similar elements.

In addition, the size and thickness of each component illustrated in the drawings are arbitrarily shown for better understanding and ease of description, but the present disclosure is not limited thereto. Thicknesses of several portions and regions are exaggerated for clear expressions.

In description, the expression “same”, “equal” may mean “substantially same”, “substantially equal”. That is, this may mean equality to a degree to which those skilled in the art can understand the equality. Other expressions may be expressions in which “substantially” is omitted.

It will be understood that, although the terms “first”, “second” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

Spatially relative terms, such as “below”, “above” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above” may encompass both an orientation of above and below. The apparatus may be otherwise oriented (e.g., rotated 90 degrees or at other orientations) and the spatially relative descriptors used herein interpreted accordingly.

Unless defined otherwise, it is to be understood that all the terms (including technical and scientific terms) used in the specification has the same meaning as those that are understood by those who skilled in the art. Further, the terms defined by the dictionary generally used should not be ideally or excessively formally defined unless clearly defined specifically.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items of X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items of X, Y, and Z (e.g., XYZ, XYY, YZ, ZZ).

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Hereinafter, exemplary embodiments of the present disclosure will be described in detail with reference to the accompanying drawings.

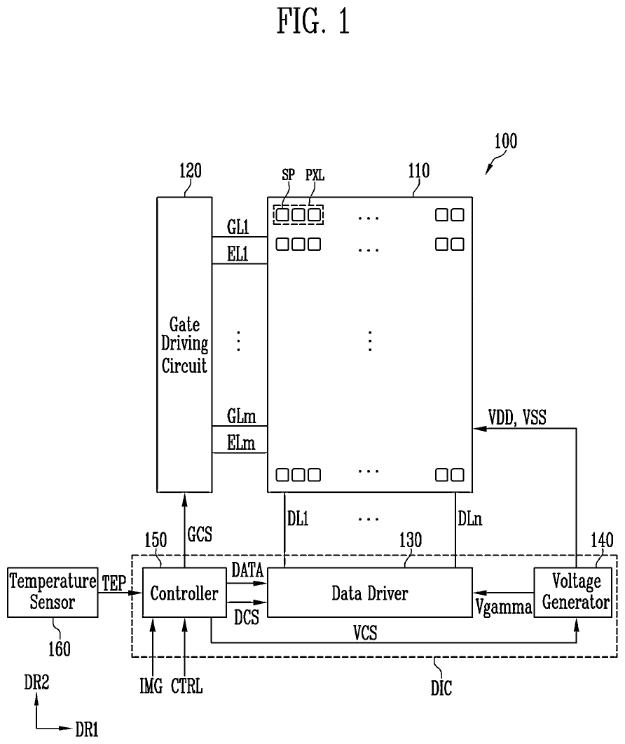

FIG. 1 is a system block diagram of a display device 100 in accordance with embodiments of the present disclosure.

Referring to FIG. 1, the display device 100 in accordance with the embodiments of the present disclosure may include a display panel 110, a gate driving circuit 120, a data driver 130, a voltage generator 140, a controller 150, and a temperature sensor 160.

The display panel 110 may include a plurality of pixels PXL, each including a plurality of sub-pixels SP. First to mth gate lines GL1 to GLm (m is an integer of 2 or more) connected to the plurality of sub-pixels SP may be disposed in the display panel 110. First to nth data lines DL1 to DLn (n is an integer of 2 or more), which are connected to the plurality of sub-pixels SP, may be disposed in the display panel 110.

The plurality of sub-pixels SP may be connected (e.g., electrically connected) to the gate driving circuit 120 through the first to mth gate lines GL1 to GLm. The plurality of sub-pixels SP may be connected (e.g., electrically connected) to the data driver 130 through the first to nth data lines DL1 to DLn.

Each of the plurality of sub-pixels SP may include at least one light emitting element configured to generate light. Each of the plurality of sub-pixels SP may generate light of a predetermined color (e.g., a specific color or a specific wavelength band) such as red, green, blue, cyan, magenta, or yellow. Two or more sub-pixels SP among the plurality of sub-pixels SP may constitute one pixel PXL. For example, three sub-pixels SP may constitute one pixel PXL as shown in FIG. 1.

The gate driving circuit 120 may be connected (e.g., electrically connected) to the plurality of sub-pixels SP (e.g., the plurality of sub-pixels SP entirely arranged in a first direction DR1) through the first to mth gate lines GL1 to GLm. The first direction DR1 may be, for example, a direction crossing the display panel 110 from one side (e.g., a left side) to the other side (e.g., a right side) of the display panel 110. The first direction DR1 may be, for example, a row direction.

The gate driving circuit 120 may output gate signals (e.g., gate signals having a turn-on level or a turn-off level) to the first to mth gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied, and/or other signals.

In embodiments, first to mth emission control lines EL1 to ELm (which are connected to the plurality of sub-pixels SP) may be further disposed in the display panel 110. The first to mth emission control lines EL1 to ELm may be disposed in the display panel 110 and extend in the row direction. The plurality of sub-pixels SP may be connected (e.g., electrically connected) to the first to mth emission control lines EL1 to ELm. In the above embodiment, the gate driving circuit 120 may include an emission control driver configured to control the first to mth emission control lines EL1 to ELm. In one embodiment, the emission control driver may be provided separately from the gate driving circuit 120. The emission control driver may operate under the control of the controller 150.

The gate driving circuit 120 may be disposed at one side of the display panel 110. However, embodiments of the present disclosure are not limited thereto. For example, the gate driving circuit 120 may be divided into two or more driving circuits which are physically and/or logically divided, and these driving circuits may be disposed at one side of the display panel 110 and the other side of the display panel 110 (e.g., the other side of the display panel 110, which faces the one side of the display panel 110). As such, in some embodiments, the gate driving circuit 120 may be disposed in various forms in the display panel 110 or at the periphery of the display panel 110.

The data driver 130 may be connected (e.g., electrically connected) to the plurality of sub-pixels SP (e.g., the plurality of sub-pixels SP entirely arranged in a second direction DR2) through the first to nth data lines DL1 to DLn. The second direction DR2 may be, for example, a direction crossing the display panel 110 from one side (e.g., a lower side) of the display panel 110 to the other side (e.g., an upper side) of the display panel 110. The second direction DR2 may be, for example, a column direction.

The data driver 130 may receive image data DATA and a data control signal DCS from the controller 150. The data driver 130 may operate in response to the data control signal DCS. In embodiments, the data control signal DCS may include one or more of a source start pulse, a source shift clock, a source output enable signal, and/or other signals.

The data driver 130 may apply grayscale voltages corresponding to the image data DATA to the first to nth data lines DL1 to DLn by using voltages (e.g., gamma voltages Vgamma) from the voltage generator 140. When a gate signal (e.g., a gate signal having the turn-on level) is applied to each of the first to mth gate lines GL1 to GLm, data signals corresponding to the image data DATA may be applied to the data line DL1 to DLn. Each of the plurality of sub-pixels SP may receive a data signal applied at a corresponding timing in response to the gate signal (e.g., the gate signal having the turn-on level). Each of the plurality of sub-pixels SP may generate light corresponding to the received data signal. Accordingly, an image may be displayed in the display panel 110.

In embodiments, each of the gate driving circuit 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may receive an input voltage from a source outside of the display device 100. The voltage generator 140 may adjust (e.g., decrease) a level of the received input voltage and regulate the voltage having the adjusted level. The voltage generator 140 may be configured to generate a plurality of voltages.

The voltage generator 140 may generate, for example, a first power voltage VDD, a second power voltage VSS, a gamma voltage Vgamma, and the like. The generated first and second power voltages VDD and VSS may be applied (e.g., commonly applied) to the plurality of sub-pixels SP. The first power voltage VDD may have a relatively high voltage level. The second power voltage VSS may have a voltage level lower than the voltage level of the first power voltage VDD. The generated gamma voltage Vgamma may be provided to the data driver 130. In other embodiments, the first power voltage VDD and/or the second power voltage VSS may be provided by an external device of the display device 100 (e.g., a Power Management Integrated Circuit (PMIC)).

In some embodiments, the voltage generator 140 may also generate another voltage. For example, the voltage generator 140 may generate an initialization voltage that is to be applied (e.g., commonly applied) to the plurality of sub-pixels SP. For example, in a sensing operation for sensing electrical characteristics of transistors and/or a light emitting element(s) of the plurality of sub-pixels SP, a predetermined reference voltage may be applied to the first to nth data lines DL1 to DLn, and the voltage generator 140 may generate the reference voltage.

The controller 150 may be configured to control overall operation of the display device 100. The controller 150 may receive, from an external source, input image data IMG and a control signal CTRL for controlling display thereof. The controller 150 may provide the gate control signal GCS, the data control signal DCS, the voltage control signal VCS, and the like in response to the received control signal CTRL.

The controller 150 may convert the input image data IMG that is suitable for the display device 100 or the display panel 110, so that the image data DATA may be output. In embodiments, the controller 150 may align the input image data IMG to be suitable for the sub-pixels SP in units of rows, to thereby output the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. In one embodiment, the data driver 130, the voltage generator 140, and the controller 150 may be components that are functionally divided in one (in the same) driver integrated circuit DIC. In one embodiment, at least one of the data driver 130, the voltage generator 140, or the controller 150 may be mounted in the driver integrated circuit DIC, and another one of the data driver 130, the voltage generator 140, or the controller 150 may be provided to be mounted in an integrated circuit different from the driver integrated circuit DIC.

The temperature sensor 160 may be configured to sense a temperature (e.g., a temperature at the periphery thereof) and generate temperature data TEP indicating the sensed temperature. In some embodiments, the temperature sensor 160 may be disposed in the display panel 110. In some embodiments, the temperature sensor 160 may be disposed to be adjacent to the display panel 110 and/or the driver integrated circuit DIC. In some embodiments, the display device 100 may include two or more temperature sensors 160.

The controller 150 may control various operations of the display device 100 in response to the temperature data TEP. In embodiments, the controller 150 may adjust the luminance of an image output from the display panel 110 in response to the temperature data TEP. For example, the controller 150 may adjust at least one of the data signals, the first power voltage VDD, or the second power voltage VSS, which are input to the display panel 110, by controlling components such as the data driver 130 and/or the voltage generator 140.

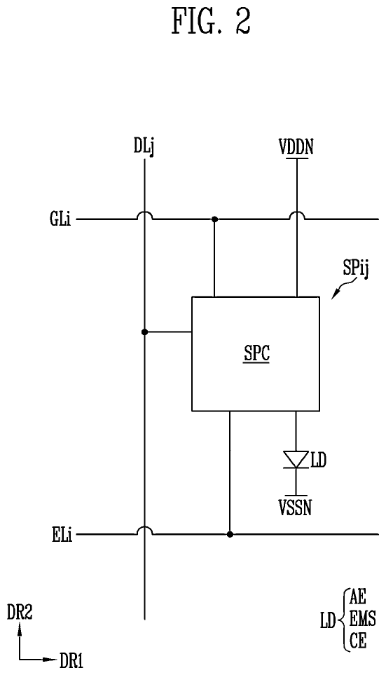

FIG. 2 is a block diagram illustrating an embodiment of any one of the sub-pixels SP shown in FIG. 1. In FIG. 2, as an example, a sub-pixel SPij is disposed on an ith row (i is an integer of 1 or more and m or less) and a jth column (j is an integer of 1 or more and n or less) among the plurality of sub-pixels SP shown in FIG. 1.

Referring to FIG. 2, the sub-pixel SPij may include a sub-pixel circuit SPC and a light emitting element LD. The light emitting element LD may be connected (e.g., electrically connected) between a first power voltage node VDDN and a second power voltage node VSSN. The first power voltage node VDDN may be a node to which the first power voltage VDD shown in FIG. 1 is applied. The second power voltage node VSSN may be a node to which the second power voltage VSS shown in FIG. 1 is applied.

The light emitting element LD may include a first electrode AE, a light emitting structure EMS, and a second electrode CE. The first electrode AE may be any one of an anode electrode or a cathode electrode of the light emitting element LD. The second electrode CE may be the other of the anode electrode or the cathode electrode of the light emitting element LD. Hereinafter, for convenience of description, a case where the first electrode AE of the light emitting element LD is the anode electrode and the second electrode CE of the light emitting element LD is the cathode electrode is described as an example.

The first electrode AE of the light emitting element LD may be connected (e.g., electrically connected) to the first power voltage node VDDN through the sub-pixel circuit SPC. The second electrode CE of the light emitting element LD may be connected (e.g., electrically connected) to the second power voltage node VSSN. For example, the first electrode AE of the light emitting element LD may be connected (e.g., electrically connected) to the first power voltage node VDDN through one or more transistors included in the sub-pixel circuit SPC.

The sub-pixel circuit SPC of the sub-pixel SPij may be connected (e.g., electrically connected) to an ith gate line GLi among the first to mth gate lines GL1 to GLm shown in FIG. 1. The sub-pixel circuit SPC of the sub-pixel SPij may be connected (e.g., electrically connected) to an ith emission control line ELi among the first to mth emission control lines EL1 to ELm shown in FIG. 1. The sub-pixel circuit SPC of the sub-pixel SPij may be connected (e.g., electrically connected) to a jth data line DLj among the first to nth data lines DL1 to DLn shown in FIG. 1. The sub-pixel circuit SPC may be configured to control an emission timing and/or an emission luminance of the light emitting element LD according to (or in response to) signals received through these signal lines.

The sub-pixel circuit SPC may operate in response to a gate signal received through the ith gate line GLi. The sub-pixel circuit SPC may also operate in response to an emission control signal received through the ith emission control line ELi.

The sub-pixel circuit SPC may receive a data signal through a jth data line DLj. The sub-pixel circuit SPC may store a voltage of the data signal (or a voltage corresponding to the data signal) in response to the gate signal (e.g., the gate signal having the turn-on level) received through the ith gate line GLi. The sub-pixel circuit SPC may adjust a timing at which a current flows through the light emitting element LD in response to the emission control signal (e.g., the emission control signal having the turn-on level) applied through the ith emission control line ELi. The magnitude of the current flowing through the light emitting element LD may vary according to a voltage stored in the sub-pixel circuit SPC. The light emitting element LD may generate light with a luminance corresponding to the data signal.

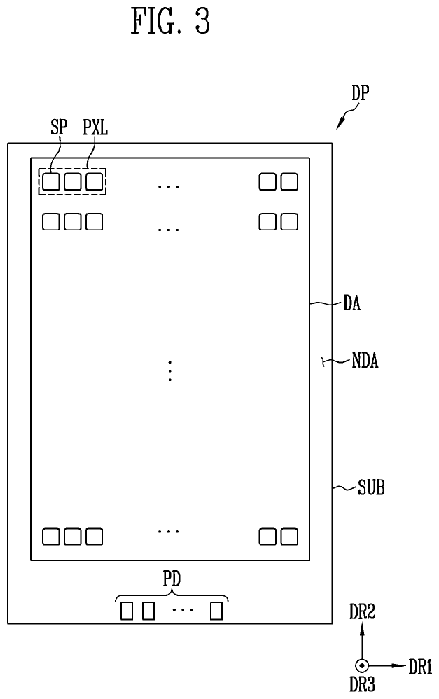

FIG. 3 is a plan view illustrating an embodiment of the display panel 110 shown in FIG. 1.

An embodiment of a display panel DP shown in FIG. 3 may be applied to the display panel 110 shown in FIG. 1.

Referring to FIG. 3, the display panel DP may include a display area DA and a non-display area NDA. The display panel DP may display an image through the display area DA. The non-display area NDA may be disposed at the periphery (e.g., in an edge area) of the display area DA and may correspond, for example, to a bezel area.

The display panel DP may include a substrate SUB, a plurality of sub-pixels SP disposed (or formed) on the substrate SUB, and a plurality of signal pads PD disposed (or formed) on the substrate SUB.

When the display panel DP in accordance with the embodiments of the present disclosure is used as a display screen of a Head Mounted Display (HMD), a Virtual Reality (VR) device, a Mixed Reality (MR) device, an Augmented Reality (AR) device, and the like, the display panel DP may be located very close to eyes of a user. In the above embodiment, it may be that the sub-pixels SP are to be integrated with a relatively high density. In order to increase integration of the sub-pixels SP, the substrate SUB in accordance with the embodiments of the present disclosure may be provided as a silicon substrate. The sub-pixels SP may be formed on the substrate SUB as the silicon substrate. The display device 100 (e.g., see FIG. 1), including the sub-pixels SP formed on the substrate SUB as the silicon substrate, may be designated as an OLED on Silicon (OLEDoS) display device.

The plurality of sub-pixels SP may be disposed in the display area DA on the substrate SUB. Referring to FIG. 3, the sub-pixels SP may be arranged in a matrix form along the first direction DR1 and the second direction DR2 intersecting the first direction DR1. However, embodiments of the present disclosure are not limited thereto. For example, the plurality of sub-pixels SP in accordance with the embodiments of the present disclosure may be arranged in a zigzag form along the first direction DR1 and the second direction DR2. For example, the plurality of sub-pixels SP may be disposed in a PENTILE™ format. The first direction DR1 may be a row direction, and the second direction DR2 may be a column direction. Two or more sub-pixels SP among the plurality of sub-pixels SP may constitute one pixel PXL.

A component for controlling the sub-pixels SP may be disposed in the non-display area NDA on the substrate SUB. For example, lines such as the first to mth gate lines GL1 to GLm and the first to nth data lines DL1 to DLn, which, for example, are shown in FIG. 1, may be disposed to extend to at least a portion of the non-display area NDA.

At least one of the gate driving circuit 120, the data driver 130, the voltage generator 140, the controller 150, or the temperature sensor 160, which are shown in FIG. 1, may be disposed (e.g., integrated) in the non-display area NDA of the display panel DP.

In an embodiment, the gate driving circuit 120 shown in FIG. 1 may be formed and disposed in the non-display area NDA of the display panel DP. In another embodiment, the gate driving circuit 120 may be implemented as a separate integrated circuit distinguished from the display panel DP to be mounted in the non-display area NDA.

In an embodiment, the temperature sensor 160 shown in FIG. 1 may be disposed in the non-display area NDA to sense a temperature of the display panel DP. The temperature sensor 160 may be disposed at a predetermined location, e.g., at a vertex or in an area corresponding thereto. In one embodiment, two or more temperature sensors 160 may be disposed in the display panel DP.

The signal pads PD may be disposed in the non-display area NDA on the substrate SUB. The signal pads PD may be electrically connected to the sub-pixels SP through the lines. For example, the signal pads PD may be connected to the sub-pixels SP through the first to nth data lines DL1 to DLn.

The signal pads PD may interface the display panel DP, for example, with other components of the display device 100 (e.g., see FIG. 1). In embodiments, voltages and signals, which are to be used for operations of components included in the display panel DP, may be provided from the driver integrated circuit DIC shown in FIG. 1 through the signal pads PD. For example, the first to nth data lines DL1 to DLn (see FIG. 1) may be connected to the driver integrated circuit DIC through the signal pads PD. For example, the first and second power voltages VDD and VSS (see FIG. 1) may be received from the driver integrated circuit DIC through the signal pads PD. In an embodiment in which the gate driving circuit 120 is mounted in the display panel DP, the gate control signal GCS may be transmitted from the driver integrated circuit DIC to the gate driving circuit 120 through the signal pads PD.

In embodiments, a circuit board may be electrically connected to the signal pads PD, using a conductive adhesive member such as an anisotropic conductive film. The circuit board may be a Flexible Printed Circuit Board (FPCB) or a flexible film, which has a flexible material. The driver integrated circuit DIC (see FIG. 1) may be mounted on the circuit board to be electrically connected to the signal pads PD.

In embodiments, the display area DA may have one of various shapes. For example, the display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or the substrate SUB may include rigid or flexible materials.

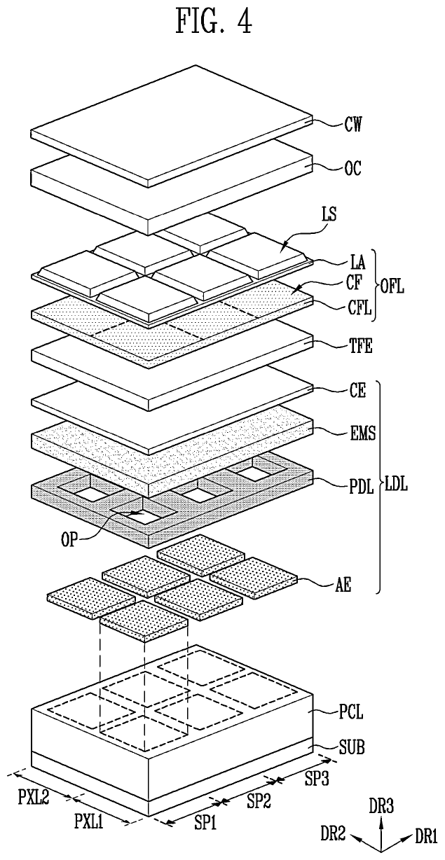

FIG. 4 is an exploded perspective view illustrating a portion of the display panel DP shown in FIG. 3 according to an embodiment.

In FIG. 4, for clear and brief description, a portion of the display panel DP, which corresponds to first and second pixels PXL1 and PXL2 among the pixels PXL shown in FIG. 3, is schematically illustrated. A portion of the display panel DP, which corresponds to the other pixels PXL, may also be configured identically.

Referring to FIGS. 3 and 4, the first and second pixels PXL1 and PXL2 may be adjacent to each other when arranged in the second direction DR2. Each of the first and second pixels PXL1 and PXL2 may include a plurality of sub-pixels SP. Referring to FIG. 4, each of the first and second pixels PXL1 and PXL2 may include first, second, and third sub-pixels SP1, SP2, and SP3 arranged in the first direction DR1. However, embodiments of the present disclosure are not limited thereto. For example, each of the first and second pixels PXL1 and PXL2 may include four sub-pixels SP or include two sub-pixels SP.

In FIG. 4, it is illustrated that the first to third sub-pixels SP1 to SP3 may have quadrangular shapes when viewed in a third direction DR3 intersecting the first and second directions DR1 and DR2 (e.g., perpendicular to the first and second directions DR1 and DR2), and have the same size. However, embodiments are not limited thereto. The first to third sub-pixels SP1 to SP3 may be modified to have various shapes.

The display panel DP may include a substrate SUB, a pixel circuit layer PCL, a light emitting element layer LDL, a thin film encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see FIG. 2) of each of the first to third sub-pixels SP1 to SP3. The sub-pixel circuit SPC may include at least two transistors and at least one capacitor. Each transistor may include a semiconductor portion including a source region, a drain region, and a channel region, and a gate electrode overlapping with the semiconductor portion (e.g., the channel region). In embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. In embodiments, when the substrate SUB is provided as a glass substrate or a PI substrate, the semiconductor portion and the gate electrode may be included in the pixel circuit layer PCL. The capacitor may include electrodes spaced apart from each other (e.g., face each other), with a dielectric disposed therebetween. For example, each capacitor may include electrodes spaced apart from each other on a plane defined by the first and second directions DR1 and DR2. For example, the capacitor may include electrodes spaced apart from each other in the third direction DR3 with a dielectric insulating layer interposed therebetween.

The lines of the pixel circuit layer PCL may include signal lines, e.g., a gate line, an emission control line, a data line, and the like, which are connected to each of the first to third sub-pixels SP1 to SP3. The lines may further include a line connected to the first power voltage node VDDN shown in FIG. 2. The lines may further include a line connected to the second power voltage node VSSN shown in FIG. 2.

The light emitting element layer LDL may include first electrodes AE, a pixel defining layer PDL, a light emitting structure EMS, and a second electrode CE. The first electrodes AE may be disposed on the pixel circuit layer PCL and, for example, may be anode electrodes. The first electrodes AE may be connected to (e.g., be in contact with) the circuit elements of the pixel circuit layer PCL. The first electrodes AE may include an opaque conductive material capable of reflecting light. However, embodiments of the present disclosure are not limited thereto.

The pixel defining layer PDL may be disposed on the first electrodes AE. The pixel defining layer PDL may include an opening OP exposing a portion of each of the first electrodes AE. The opening OP of the pixel defining layer PDL may be an emission area of each of the first to third sub-pixels SP1 to SP3.

In embodiments, the pixel defining layer PDL may include an inorganic material. In the above embodiment, the pixel defining layer PDL may include an inorganic layer (e.g., a plurality of stacked inorganic layers). For example, the pixel defining layer PDL may include silicon oxide (SiOₓ) and/or silicon nitride (SiNₓ). In other embodiments, the pixel defining layer PDL may include an organic layer including an organic material. However, the material constituting the pixel defining layer PDL in accordance with the embodiments of the present disclosure is not limited as described above.

The light emitting structure EMS may be disposed on the first electrodes AE exposed by the openings OP of the pixel defining layer PDL. The light emitting structure EMS may include at least one functional layer. The light emitting structure EMS may include, for example, a plurality of functional layers such as a light emitting layer configured to generate light, an electron transport layer configured to transport electrons, and a hole transport layer configured to transport holes.

In embodiments, the light emitting structure EMS may fill the openings OP of the pixel defining layer PDL. In embodiments, the light emitting structure EMS may be entirely disposed on the top of the pixel defining layer PDL. For example, the light emitting structure EMS may extend throughout the first to third sub-pixels SP1 to SP3. In the above embodiment, at least some of the functional layers in the light emitting structure EMS may be cut or curved at boundaries between the first to third sub-pixels SP1 to SP3. However, embodiments of the present disclosure are not limited thereto. For example, portions of the light emitting structure EMS, which correspond to the first to third sub-pixels SP1 to SP3, may be separated from each other, and each of the portions may be disposed in the openings OP of the pixel defining layer PDL.

The second electrode CE may be disposed on the light emitting structure EMS and, for example, may be a cathode electrode. The second electrode CE may extend throughout (or overlap) the first to third sub-pixels SP1 to SP3. The second electrode CE may be provided as a common electrode commonly connected to the first to third sub-pixels SP1 to SP3.

The second electrode CE may have light transmissivity. For example, the second electrode CE may be a thin metal layer having a thickness to a degree to which light emitted from the light emitting structure EMS can be transmitted therethrough. The second electrode CE may be formed of a metal material to have a relatively thin thickness or be formed of a conductive material having light transmissivity (e.g., transparency). In embodiments, the second electrode CE may include at least one of various transparent conductive materials including indium tin oxide (ITO), indium zinc oxide (IZO), indium tin zinc oxide (ITZO), aluminum zinc oxide, gallium zinc oxide, zinc tin oxide, and gallium tin oxide. However, the material constituting the second electrode CE in accordance with the embodiments of the present disclosure is not limited as described above. In one embodiment, the second electrode CE may serve as a half mirror which allows light emitted from the light emitting structure EMS to be partially transmitted therethrough and allows light emitted from the light emitting structure EMS to be partially reflected therefrom.

It may be understood that any one of the first electrodes AE, a portion of the light emitting structure EMS (which overlaps therewith), and a portion of the second electrode CE (which overlaps therewith) constitute one light emitting element LD (e.g., see FIG. 2). Each of light emitting elements LD of the first to third sub-pixels SP1 to SP3 may include one first electrode AE, a portion of the light emitting structure EMS which overlaps therewith, and a portion of the second electrode CE which overlaps therewith. In each of the first to third sub-pixels SP1 to SP3, holes injected from the first electrode AE and electrons injected from the second electrode CE may be transported into the light emitting structure EMS to form excitons, and light may be generated when the excitons are changed from an excited state to a ground state. The luminance of the light may be determined according to an amount of current flowing through the light emitting structure EMS. A wavelength band of the generated light may be determined according to a configuration of the light emitting structure EMS.

The thin film encapsulation layer TFE may be disposed over the second electrode CE. The thin film encapsulation layer TFE may cover the light emitting element layer LDL and/or the pixel circuit layer PCL. The thin film encapsulation layer TFE may be configured to prevent oxygen and/or moisture from infiltrating into the light emitting element layer LDL. In embodiments, the thin film encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the thin film encapsulation layer TFE are not limited as described above.

In order to improve encapsulation efficiency of the thin film encapsulation layer TFE, the thin film encapsulation layer TFE may further include a thin film including aluminum oxide (AlOₓ). The thin film including the aluminum oxide may be located on a top surface of the thin film encapsulation layer TFE (which faces the optical functional layer OFL) and/or a bottom surface of the thin film encapsulation layer TFE which faces the light emitting element layer LDL. The thin film including the aluminum oxide may be formed, for example, through an Atomic Layer Deposition (ALD) process. However, embodiments of the present disclosure are not limited thereto. The thin film encapsulation layer TFE may further include a thin film formed of at least one of various materials suitable for improvement of the encapsulation efficiency.

The optical functional layer OFL may be disposed on the thin film encapsulation layer TFE. The optical functional layer OFL may include a color filter layer CFL and a lens array LA. In embodiments, the optical functional layer OFL may be attached to the thin film encapsulation layer TFE through an adhesive layer. For example, the optical functional layer OFL may be separately manufactured to be attached to the thin film encapsulation layer TFE through the adhesive layer. The adhesive layer may further perform a function of protecting lower layers including the thin film encapsulation layer TFE.

The color filter layer CFL may be disposed between the thin film encapsulation layer TFE and the lens array LA. The color filter layer CFL may be configured to filter light emitted from the light emitting structure EMS, to thereby selectively output light having a wavelength band corresponding to each sub-pixel SP.

The color filter layer CFL may include color filters CF respectively corresponding to the first to third sub-pixels SP1 to SP3. Each of the color filters CF may allow light having a wavelength band corresponding to a corresponding sub-pixel SP to pass therethrough. For example, a color filter CF corresponding to the first sub-pixel SP1 may allow light of a first (e.g., red) color to pass therethrough, a color filter CF corresponding to the second sub-pixel SP2 may allow light of a second (e.g., green) color to pass therethrough, and a color filter corresponding to the third sub-pixel SP3 may allow light of a third (e.g., blue) color to pass therethrough. According to light emitted from the light emitting structure EMS in each sub-pixel SP, at least some of the color filters CF may be omitted. In some embodiments, the color filter layer CFL may be omitted. In embodiments, the color filters CF may overlap (e.g., partially overlap) with each other in boundary areas between the first to third sub-pixels SP1 to SP3. In other embodiments, the color filters CF may be spaced apart from each other in the boundary areas between the first to third sub-pixels SP1 to SP3, and a black matrix may be provided between the color filters CF.

The lens array LA may be disposed on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. In embodiments, the lenses LS may include an organic material. In embodiments, the lenses LS may include an acryl-based material. However, the material of the lenses LS is not limited thereto.

In embodiments, as compared with the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. For example, in a central area of the display area DA, the center of the color filter CF and the center of the lens LS may be aligned or overlap with the center of a corresponding opening OP of the pixel defining layer PDL when viewed in the third direction DR3. For example, in the central area of the display area DA, the opening OP of the pixel defining layer PDL may completely overlap with a corresponding color filter CF of the color filter layer CFL and a corresponding lens LS of the lens array LA. In an area adjacent to the non-display area NDA of the display area DA, the center of the color filter CF and the center of the lens LS may be shifted in a plane direction from the center of the opening OP of the pixel defining layer PDL when viewed in the third direction DR3. For example, in an area adjacent to the non-display area NDA of the display area DA, the opening OP of the pixel defining layer PDL may partially overlap with a corresponding color filter CF of the color filter layer CFL and a corresponding lens LS of the lens array LA. Accordingly, at the center of the display area DA, light emitted from the light emitting structure EMS can be efficiently output in a normal direction of the display surface. At an outer portion of the display area DA, light emitted from the light emitting structure EMS can be efficiently output in a direction inclined by a predetermined angle with respect to the normal direction.

The overcoat layer OC may be disposed over the lens array LA. The overcoat layer OC may cover the optical functional layer OFL, the thin film encapsulation layer TFE, the light emitting structure EMS, and/or the pixel circuit layer PCL. The overcoat layer OC may include various materials suitable for protecting lower layers thereof from foreign matters such as dust, debris and moisture. For example, the overcoat layer OC may include an inorganic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index different from (e.g., higher than) the refractive index of the overcoat layer OC. The cover window CW may include glass, but embodiments are not limited thereto. For example, the cover window CW may be an encapsulation glass configured to protect components disposed on the bottom thereof. In other embodiments, the cover window CW may be omitted.

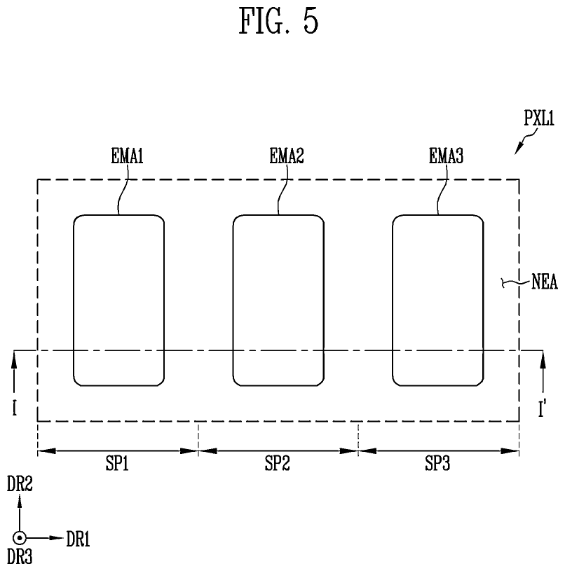

FIG. 5 is a plan view illustrating an embodiment of any one of the pixels shown in FIG. 4. In FIG. 5, for clear and brief description, the first pixel PXL1 among the first and second pixels PXL1 and PXL2 shown in FIG. 4 is schematically illustrated. The other pixels may be configured identically to the first pixel PXL1. The first pixel PXL1 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (e.g., see FIG. 4), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3. As described with reference to FIG. 4, each emission area may be understood as an opening OP of the pixel defining layer PDL, which corresponds to each of the first to third sub-pixels SP1 to SP3.

To increase resolution, efforts are being made to reduce the sizes of pixels PXL. As the size of the first pixel PXL1 becomes smaller, the distance between the first to third sub-pixels SP1 to SP3 may become smaller. Accordingly, a leakage current may flow in an adjacent sub-pixel SP. Therefore, display quality may be deteriorated by the leakage current. In addition, the leakage current may flow in an adjacent sub-pixel SP through the light emitting structure EMS (e.g., see FIG. 4). To reduce (or prevent) the leakage current from flowing in the adjacent sub-pixel SP, at least a portion of the light emitting structure EMS may be removed through a hole.

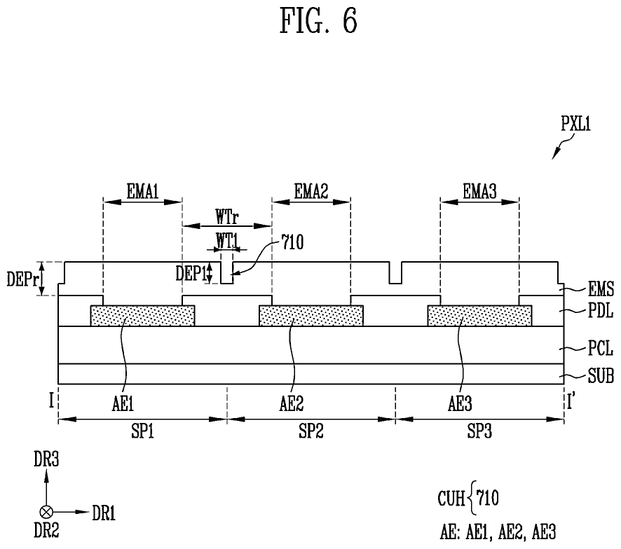

FIG. 6 is a sectional view illustrating a light emitting structure EMS including holes CUH in accordance with an embodiment of the present disclosure, taken along line I-I′ of the pixel shown in FIG. 5. In the sectional view shown in FIG. 6, for convenience of description, the second electrode CE shown in FIG. 4 and the layers located on the second electrode CE are not illustrated.

Referring to FIG. 6, the following is shown: a pixel circuit layer PCL, a first electrode AE, a pixel defining layer PDL, and a light emitting structure EMS stacked on a substrate SUB. The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1 to SP3. For example, the substrate SUB and the pixel circuit layer PCL may include a transistor of the first sub-pixel SP1, a transistor of the second sub-pixel SP2, and a transistor of the third sub-pixel SP3.

Each of the first to third sub-pixels SP1 to SP3 may include a first electrode AE. Referring to FIG. 6, a first electrode AE1 of the first sub-pixel SP1, a first electrode AE2 of the second sub-pixel SP2, and a first electrode AE3 of the third sub-pixel SP3 are illustrated. The first electrodes AE1 to AE3 may have shapes similar to shapes of the first to third emission areas EMA1 to EMA3, for example, as shown in FIG. 5 when viewed in the third direction DR3. In embodiments, the first electrodes AE1 to AE3 may include at least one of transparent conductive materials such as Indium Tin Oxide (ITO), Indium Zinc Oxide (IZO), Zinc Oxide (ZnO), Indium Gallium Zinc Oxide (IGZO), and Indium Tin Zinc Oxide (ITZO). However, the material of the first electrodes AE1 to AE3 is not limited thereto. For example, the first electrodes AE1 to AE3 may include titanium nitride.

The pixel defining layer PDL may be disposed on portions of the first electrodes AE1 to AE3 and the pixel circuit layer PCL (e.g., a planarization layer of the pixel circuit layer PCL). The pixel defining layer PDL may include openings OP (e.g., see also FIG. 4) exposing portions of respective ones of the first electrodes AE1 to AE3. The openings OP of the pixel defining layer PDL may define emission areas of the first to third sub-pixels SP1 to SP3. The pixel defining layer PDL may define first to third emission areas EMA1 to EMA3 while being disposed in the non-emission area NEA shown in FIG. 5.

In embodiments, the pixel defining layer PDL may include a plurality of inorganic insulating layers. Each of the plurality of inorganic insulating layers may include at least one of silicon oxide (SiOₓ) or silicon nitride (SiNₓ). For example, the pixel defining layer PDL may include first to third inorganic insulating layers which are sequentially stacked, and each of the first to third inorganic insulating layers may include silicon nitride, silicon oxide, and silicon oxynitride. However, embodiments of the present disclosure are not limited thereto. The first to third inorganic insulating layers may have a step-shaped section in an area adjacent to the opening OP.

The light emitting structure EMS may be disposed on the first electrodes AE exposed by the openings OP (e.g., see also FIG. 4) of the pixel defining layer PDL. The light emitting structure EMS may fill the openings OP of the pixel defining layer PDL and may be entirely disposed throughout the first to third sub-pixels SP1 to SP3. The light emitting structure EMS may be formed through a process such as vacuum deposition or inkjet printing.

In accordance with one or more embodiments described herein, as shown in FIG. 6, at least a portion of the light emitting structure EMS may be removed in an area located between adjacent ones of the sub-pixels SP. A hole CUH may correspond to an area in which at least a portion of the light emitting structure EMS is removed. As will be described in greater detail, the hole CUH may prevent leakage current from migrating between adjacent sub-pixels SP. In FIG. 6, a first hole 710 is illustrated as an embodiment of the hole CUH. Referring to FIG. 6, the first hole 710 in accordance with the embodiments of the present disclosure may be formed by removing at least a portion of the light emitting structure EMS.

For example, the first hole 710 may be located in a boundary area between adjacent sub-pixels SP. Referring to FIG. 6, the first hole 710 may be located in a boundary area between the first sub-pixel SP1 and the second sub-pixel SP2. Another first hole 710 may be located in a boundary area between the second sub-pixel SP2 and the third sub-pixel SP3 to prevent leakage current from migrating between these sub-pixels SP.

As further shown in FIG. 6, the first hole 710 may be located between the first electrode AE1 of the first sub-pixel SP1 and the first electrode AE2 of the second sub-pixel SP2. The other first hole 710 may be located between the first electrode AE2 of the second sub-pixel SP2 and the first electrode AE3 of the third sub-pixel SP3.

The width (e.g., width in the first direction DR1 or the second direction DR2) of the first hole 710 may be a first width WT1. The depth (e.g., a depth in the third direction DR3) of the first hole 710 may be a first depth DEP1. The width and the depth of the first hole 710 may be described relative to the pixel defining layer PDL. For example, the width of a top surface of the pixel defining layer PDL may be a reference width WTr. The distance from a top surface of the light emitting structure EMS to the top surface of the pixel defining layer PDL may be a reference depth DEPr. In accordance with one embodiment, the width (or the first width WT1) of the first hole 710 may be less than the reference width WTr, and the depth (or the first depth DEP1) of the first hole 710 may be less than the reference depth DEPr.

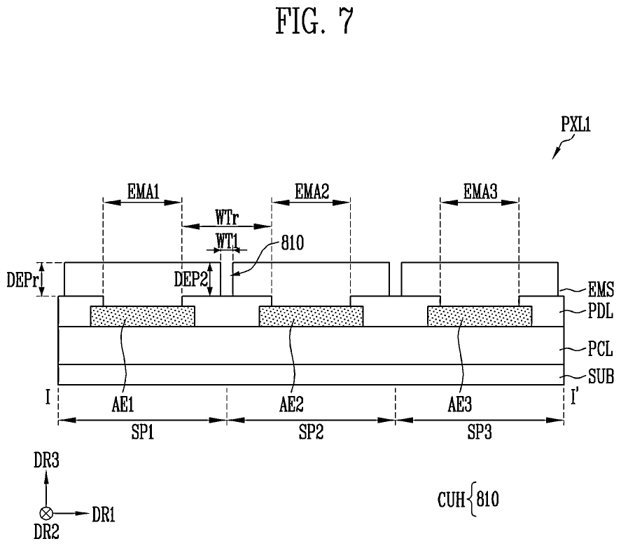

FIG. 7 is a sectional view illustrating a light emitting structure EMS including a hole CUH in accordance with another embodiment of the present disclosure, taken along line I-I′ of the pixel shown in FIG. 5.

Referring to FIG. 7, a second hole 810 is illustrated as another embodiment of the hole CUH. Referring to FIG. 7, the second hole 810 in accordance with the embodiments of the present disclosure may be formed by removing at least a portion of the light emitting structure EMS. Like the first hole 710 in the previous embodiment, the second hole 810 may be located in a boundary area between adjacent sub-pixels SP. For example, referring to FIG. 7, the second hole 810 may be located at a boundary area between the first sub-pixel SP1 and the second sub-pixel SP2. Another second hole 810 may be located at a boundary area between the second sub-pixel SP2 and the third sub-pixel SP3. The second hole 810 may be located between the first electrode AE1 of the first sub-pixel SP1 and the first electrode AE2 of the second sub-pixel SP2. The other second hole 810 may be located between the first electrode AE2 of the second sub-pixel SP2 and the first electrode AE3 of the third sub-pixel SP3. As described in detail, the second hole 810 may prevent leakage current from migrating between adjacent sub-pixels SP.

The width (e.g., a width in the first direction DR1 or the second direction DR2) of the second hole 810 may be a first width WT1. The depth (e.g., a depth in the third direction DR3) of the second hole 810 may be a second depth DEP2. The width and the depth of the second hole 810 may be described relative to the pixel defining layer PDL. The width of a top surface of the pixel defining layer PDL may be a reference width WTr. The distance from a top surface of the light emitting structure EMS to the top surface of the pixel defining layer PDL may be a reference depth DEPr. The width (or the first width WT1) of the second hole 810 may be less than the reference width WTr. In accordance with the present embodiment, the depth (or the second depth DEP2) of the second hole 810 may be equal (or substantially equal) to the reference depth DEPr. As shown, at least a portion of the pixel defining layer PDL (e.g., the top surface of the pixel defining layer PDL) may be exposed by the second hole 810.

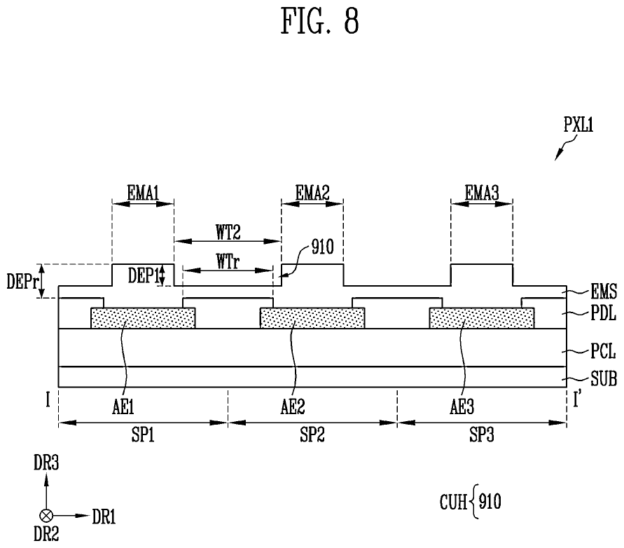

FIG. 8 is a sectional view illustrating a light emitting structure EMS including a hole CUH in accordance with another embodiment of the present disclosure, taken along line I-I′ of the pixel shown in FIG. 5.

Referring to FIG. 8, a third hole 910 is illustrated as another embodiment of the hole CUH. Referring to FIG. 8, the third hole 910 in accordance with the embodiments of the present disclosure may be formed by removing at least a portion of the light emitting structure EMS. The third hole 910 may be located at a boundary area between adjacent sub-pixels SP. Referring to FIG. 8, the third hole 910 may be located at a boundary area between the first sub-pixel SP1 and the second sub-pixel SP2. Another third hole 910 may be located between the second sub-pixel SP2 and the third sub-pixel SP3. When positioned at these locations the third holes 910 may prevent migration of leakage current between the adjacent sub-pixels SP.

The third hole 910 may overlap (e.g., overlap in the third direction DR3) with at least a portion of the first electrode AE1 of the first sub-pixel SP1. In one embodiment, the third hole 910 may also overlap (e.g., overlap in the third direction DR3) with at least a portion of the first electrode AE2 of the second sub-pixel SP2. The other third hole 910 may overlap (e.g., overlap in the third direction DR3) with at least a portion of the first electrode AE3 of the third sub-pixel SP3. The degree to which the third hole 910 overlaps adjacent ones of the first electrodes AE may be the same or different.

The width (e.g., a width in the first direction DR1 or the second direction DR2) of the third hole 910 may be a second width WT2. The depth (e.g., a depth in the third direction DR3) of the third hole 910 may be the first depth DEP1. The width and the depth of the third hole 910 may be described relative to the pixel defining layer PDL. The width of a top surface of the pixel defining layer PDL may be the reference width WTr. The distance from a top surface of the light emitting structure EMS to the top surface of the pixel defining layer PDL may be the reference depth DEPr. The width (or the second width WT2) of the third hole 910 may be greater than the reference width WTr, and the depth (or the first depth DEP1) of the third hole 910 may be less than the reference depth DEPr.

The third hole 910 may define the non-emission area NEA (see FIG. 5). The third hole 910 may overlap (e.g., overlap in the third direction DR3) with at least some of the first electrodes AE1 to AE3.

The hole CUH described with reference to FIGS. 6 to 8 may be formed, for example, using a wire (e.g., a nano wire). The wire may extend in the first direction DR1 or the second direction DR2. For example, the hole CUH may be formed by allowing the wire to generate heat. For example, heat generated from the wire may be transferred to the light emitting structure EMS by allowing the wire to be in contact with an area in which the hole CUH is to be formed on the light emitting structure EMS. The heat may be generated when a voltage is applied to the wire. At least a portion of the light emitting structure EMS may be removed by the heat generated from the wire. The wire may move in one direction (e.g., the third direction DR3), thereby removing at least a corresponding portion of the light emitting structure EMS (e.g., removing the light emitting structure EMS by a predetermined depth as previously described).

According to the manufacturing method used to form the hole CUH using the wire, the hole CUH may be formed regardless of any material located while overlapping (e.g., located while overlapping in the third direction DR3) with the area in which the hole CUH is formed. For example, according to the above-described manufacturing method of the hole CUH, the hole CUH may be easily formed even when a material (e.g., the first electrode AE of the light emitting element, or the like) capable of reflecting light is located while overlapping with the area in which the hole CUH is formed.

On the other hand, when at least a portion of the light emitting structure EMS is removed using laser, the laser is reflected in an area in which a material (e.g., a metal or the like) capable of reflecting light is located under an area onto which the laser is irradiated. In this case, it may be difficult to appropriately remove the material of the light emitting structure EMS to form the hole CUH. Such a technical difficulty may occur, for example, when a display device (e.g., an OLEDoS display device) is manufactured to have pixels that are integrated with a high density or resolution.

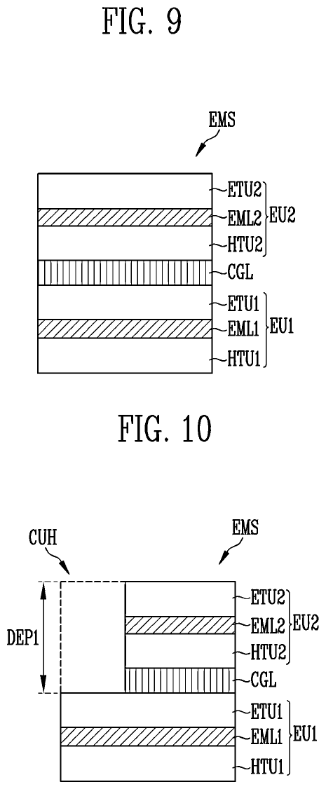

FIG. 9 is a sectional view illustrating an embodiment of a light emitting structure EMS in accordance with embodiments of the present disclosure.

Referring to FIG. 9, the light emitting structure EMS may have a tandem structure in which first and second light emitting units (or areas) EU1 and EU2 are stacked. The light emitting structure EMS may be configured substantially identically in the light emitting element LD (see FIG. 2) of each of the first to third sub-pixels SP1 to SP3 shown in FIG. 5.

Each of the first and second light emitting units EU1 and EU2 may include a light emitting layer configured to generate light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. In some embodiments, each of the first and second hole transport units HTU1 and HTU2 may further include a hole buffer layer, an electron blocking layer, and the like. The first and second hole transport units HTU1 and HTU2 may have the same configuration or different configurations.

Each of the first and second electron transport units ETU1 and ETU2 may include at least one of an electron injection layer and an electron transport layer. In some embodiments, each of the first and second electron transport units ETU1 and ETU2 may further include an electron buffer layer, a hole blocking layer, and the like. The first and second electron transport units ETU1 and ETU2 may have the same configuration or different configurations.

A connection layer may be provided in the form of a charge generation layer CGL between the first light emitting unit EU1 and the second light emitting unit EU2. The connection layer may electrically connect the first light emitting unit EU1 and the second light emitting unit EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9. For example, the n-dopant layer may include an alkali metal, an alkali earth metal, a lanthanide-based metal, or any combination thereof. However, embodiments of the present disclosure are not limited thereto.

In embodiments, the first light emitting layer EML1 and the second light emitting layer EML2 may generate light of different colors (or wavelength bands). Light respectively emitted from the first light emitting layer EML1 and the second light emitting layer EML2 may be mixed together to be viewed as white light. For example, the first light emitting layer EML1 may generate light of a blue color, and the second light emitting layer EML2 may generate light of a yellow color. In embodiments, the second light emitting layer EML2 may include a structure in which a first sub-light emitting layer configured to generate light of a red color and a second sub-light emitting layer configured to generate light of a green color are stacked. In one embodiment, red color light and green color light may be mixed together to provide the light of the yellow color. An intermediate layer (or functional layer) configured to perform a function of transporting holes and/or a function of blocking transportation of electrons may be further disposed between the first and second sub-light emitting layers.

In other embodiments, the first light emitting layer EML1 and the second light emitting layer EML2 may generate light of the same color (or wavelength band).

In embodiments, the light emitting structure EMS may be formed through a process such as vacuum deposition or inkjet printing, but embodiments are not limited thereto.

FIG. 10 is a sectional view illustrating an embodiment in which the light emitting structure EMS shown in FIG. 9 includes a hole CUH. The hole CUH may be formed by removing the charge generation layer CGL and one or more layers located on the charge generation layer CGL. Referring to FIG. 10, the hole CUH may be formed by removing (e.g., sequentially removing) corresponding portions of the second electron transport unit ETU2, the second light emitting layer EML2, the second hole transport unit HTU2, and the charge generation layer CGL. The depth of the hole CUH may be a first depth DEP1. The hole CUH shown in FIG. 10 may correspond to the first hole 710 shown in FIG. 6 or the third hole 910 shown in FIG. 8.

Without hole CUH, leakage current may be generated between adjacent sub-pixels SP due to charges generated in the charge generation layer CGL. In accordance with embodiments described herein, because the charge generation layer CGL is removed at a boundary area between the sub-pixels SP, a phenomenon in which the leakage current is generated can be reduced (or prevented), thereby preventing deterioration of images displayed by the display device.

FIG. 11 is a sectional view illustrating another embodiment in which the light emitting structure EMS shown in FIG. 9 includes a hole CUH. The hole CUH may be formed by removing the charge generation layer CGL, one or more layers located on the charge generation layer CGL, and at least one layer located under the charge generation layer CGL. Referring to FIG. 11, in one embodiment the hole CUH may be formed by removing (e.g., sequentially removing) the second electron transport unit ETU2, the second light emitting layer EML2, the second hole transport unit HTU2, the charge generation layer CGL, the first electron transport unit ETU1, the first light emitting layer EML1, and the first hole transport unit HTU1. The depth of the hole CUH may be a second depth DEP2. The hole CUH shown in FIG. 11 may correspond to the second hole 810 shown in FIG. 7.

Without hole CUH, leakage current may be generated between adjacent sub-pixels SP due to charges generated in the charge generation layer CGL. In accordance with one or more embodiments, the charge generation layer CGL is removed at a boundary area between the sub-pixels SP, so that a phenomenon in which the leakage current is generated can be reduced (or prevented), thereby preventing deterioration of images generated by the display device.

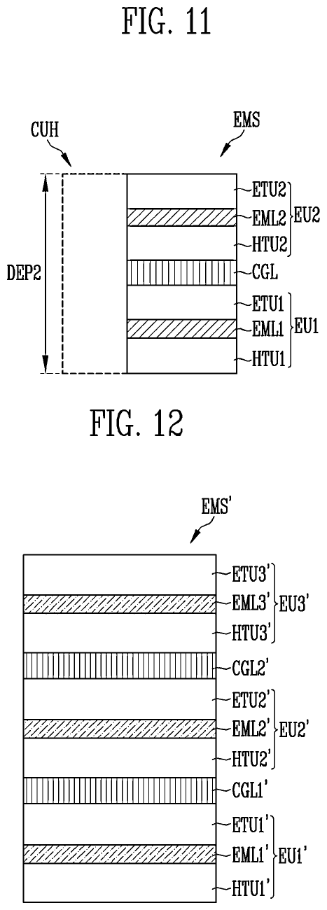

FIG. 12 is a sectional view illustrating another embodiment of a light emitting structure EMS′ in accordance with embodiments of the present disclosure.

Referring to FIG. 12, the light emitting structure EMS′ may have a tandem structure in which first to third light emitting units EU1′ to EU3′ are stacked. Each of the first to third light emitting units EU1′ to EU3′ may include a light emitting layer configured to generate light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer. In some embodiments, each of the first to third hole transport units HTU1′ to HTU3′ may further include a hole buffer layer, an electron blocking layer, and the like. The first to third hole transport units HTU1′ to HTU3′ may have the same configuration or have different configurations.

Each of the first to third electron transport units ETU1′ to ETU3′ may include at least one of an electron injection layer and an electron transport layer. In some embodiments, each of the first to third electron transport units ETU1′ to ETU3′ may further include an electron buffer layer, a hole blocking layer, and the like. The first to third electron transport units ETU1′ to ETU3′ may have the same configuration or different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In embodiments, the first to third light emitting layers EML1′ to EML3′ may generate light of different colors (or wavelength bands). Light respectively emitted from the first to third light emitting layers EML1′ to EML3′ may be mixed together to form white light. For example, the first light emitting layer EML1′ may generate light of a first wavelength band (e.g., a blue color), the second light emitting layer EML2′ may generate light of a second wavelength band (e.g., a green color), and the third light emitting layer EML3′ may generate light of a third wavelength band (e.g., a red color). In other embodiments, at least two light emitting layers of the first to third light emitting layers EML1′ to EML3′ may generate light of the same color (or wavelength band).

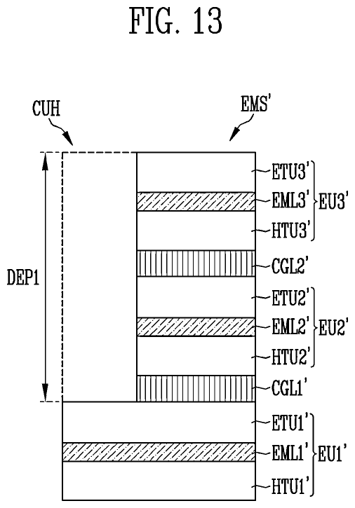

FIG. 13 is a sectional view illustrating an embodiment in which the light emitting structure EMS′ shown in FIG. 12 includes a hole CUH. The hole CUH may be formed by removing the first charge generation layer CGL1′ and one or more layers located on the first charge generation layer CGL1′. For example, as shown in FIG. 13, the hole CUH may be formed by removing (e.g., sequentially removing) the third electron transport unit ETU3′, the third light emitting layer EML3′, the third hole transport unit HTU3′, the second charge generation layer CGL2′, the second electron transport unit ETU2′, the second light emitting layer EML2′, the second hole transport unit HTU2′, and the first charge generation layer CGL1′

The depth of the hole CUH may be a first depth DEP1. The hole CUH shown in FIG. 13 may correspond to the first hole 710 shown in FIG. 6 or the third hole 910 shown in FIG. 8.

Without hole CUH, leakage current may be generated between adjacent sub-pixels SP due to charges generated in the first charge generation layer CGL1′ and/or the second charge generation layer CGL2′. In accordance with the present embodiment, the first charge generation layer CGL1′ and the second charge generation layer CGL2′ are removed at a boundary area between the sub-pixels SP, so that a phenomenon in which the leakage current is generated can be reduced (or prevented), thereby preventing deterioration of images generated by the display device.

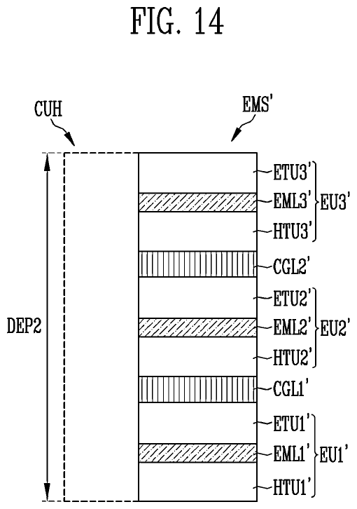

FIG. 14 is a sectional view illustrating another embodiment in which the light emitting structure EMS′ shown in FIG. 12 includes a hole CUH. The hole CUH may be formed by removing the first charge generation layer CGL1′, one or more layers located on the first charge generation layer CGL1′, and at least one layer located under the first charge generation layer CGL1′. Referring to FIG. 14, the hole CUH may be formed by removing (e.g., sequentially removing) the third electron transport unit ETU3′, the third light emitting layer EML3′, the third hole transport unit HTU3′, the second charge generation layer CGL2′, the second electron transport unit ETU2′, the second light emitting layer EML2′, the second hole transport unit HTU2′, the first charge generation layer CGL1′, the first electron transport unit ETU1′, the first light emitting layer EML1′, and the first hole transport unit HTU1′. The depth of the hole CUH may be a second depth DEP2. The hole CUH shown in FIG. 14 may correspond to the second hole 810 shown in FIG. 7.

Without hole CUH, leakage current may be generated between adjacent sub-pixels SP due to charges generated in the first charge generation layer CGL1′ and/or the second charge generation layer CGL2′. In accordance with one or more embodiments, the first charge generation layer CGL1′ and the second charge generation layer CGL2′ are removed at a boundary area between the sub-pixels SP, so that a phenomenon in which the leakage current is generated can be reduced (or prevented), thereby preventing deterioration of images displayed by the display device.

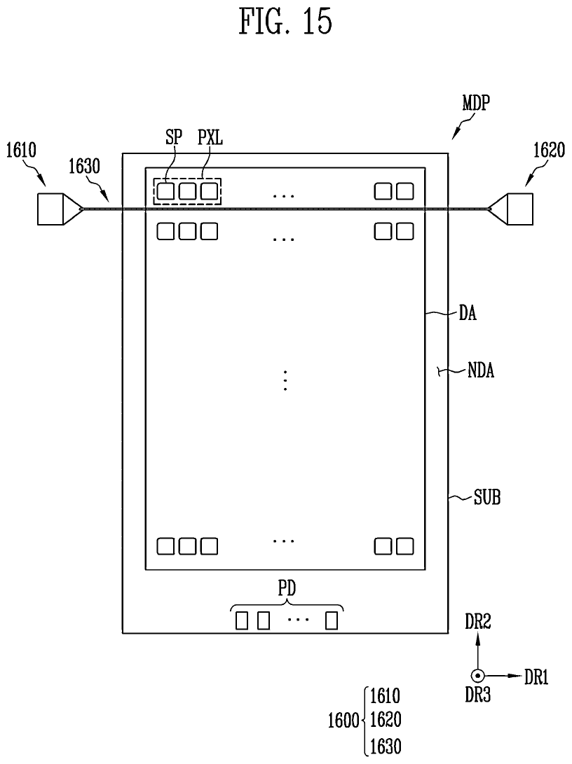

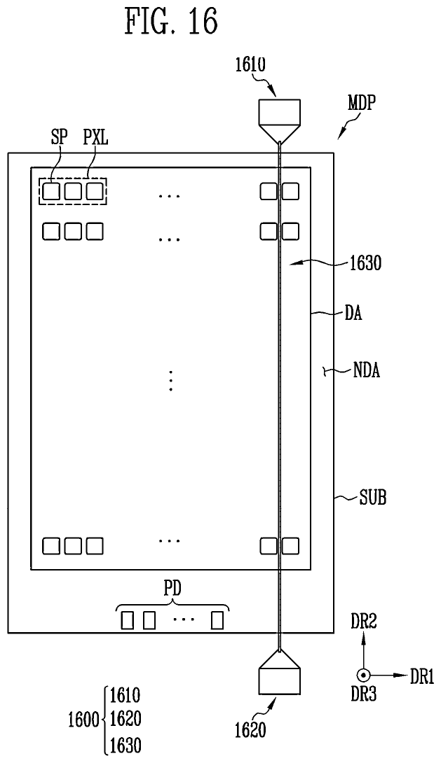

FIG. 15 is a plan view illustrating a display panel MDP in which a hole is generated in one direction by a hole generator 1600 in accordance with embodiments of the present disclosure. More specifically, FIG. 15 shows manufacture of a display panel MDP. The display panel MDP may be one in which components up to a light emitting structure EMS (e.g., see FIG. 4) are formed on the substrate SUB. The hole generator 1600 may be configured to form a hole in the display panel MDP.

Referring to FIG. 15, the hole generator 1600 may include a first unit 1610, a second unit 1620, and a wire 1630. The first unit 1610 and the second unit 1620 may be located to be spaced apart from each other, with the display panel MDP interposed therebetween. The wire 1630 has a first end connected to the first unit 1610, and a second end connected to the second unit 1620. The wire 1630 may include a conductive material (e.g., a metal).

The first and second units 1610 and 1620 may supply voltages of predetermined levels. For example, one (e.g., the first unit 1610) of the first unit 1610 or the second unit 1620 may supply a high-potential voltage, and the other (e.g., the second unit 1620) of the first unit 1610 or the second unit 1620 may supply a low-potential voltage.

The high-potential voltage may be applied to the one end of the wire 1630, and the low-potential voltage may be applied to the other end of the wire 1630. A voltage may be applied to the wire 1630, and heat may be generated in the wire 1630 by resistance of the wire 1630. A hole may be formed in the display panel MDP by the heat generated in the wire 1630. The wire 1630 may include silver (Ag), but may be made of a different conductive material in another embodiment. The wire 1630 may have a predetermined width. For example, the wire 1630 may have a width of about 200 nm (nanometer), but the embodiments of the present disclosure are not limited thereto.

Referring to FIG. 15, the wire 1630 may extend in the first direction DR1. The first unit 1610 and the second unit 1620 may move in the second direction DR2 (or a direction horizontal to the second direction DR2). In one embodiment, the display panel MDP may move in the second direction DR2 (or the direction horizontal to the second direction DR2). Accordingly, holes may be sequentially formed in the display panel MDP to reduce the generation of leakage current between adjacent sub-pixels SP as previously described.

Referring to FIG. 15, an embodiment is illustrated in which a hole CUH (e.g., see FIGS. 6 to 8) is formed to entirely extend in the first direction DR1 on the substrate SUB using the hole generator 1600. However, embodiments of the present disclosure are not limited thereto, and, for example, the hole CUH may be partially (or locally) formed in a partial area on the substrate SUB.

FIG. 16 is a plan view illustrating the display panel MDP in which a hole is generated in another direction by the hole generator 1600 in accordance with embodiments of the present disclosure.

Referring to FIG. 16, the wire 1630 may extend in the second direction DR2. The first unit 1610 and the second unit 1620 may move in the first direction DR1 (or a direction horizontal to the first direction DR1). In one embodiment, the display panel MDP may move in the first direction DR1 (or the direction horizontal to the first direction DR1). Accordingly, holes may be sequentially formed in the display panel MDP to reduce the generation of leakage current between adjacent sub-pixels SP as previously described.

As compared with FIG. 15, it is illustrated that the hole generator 1600 is rotated by 90 degrees clockwise in a state in which the substrate SUB is fixed. However, embodiments of the present disclosure are not limited thereto. For example, at least one of the substrate SUB and the hole generator 1600 may be rotated by 90 degrees. For example, each of the substrate SUB and the hole generator 1600 may be rotated by a predetermined angle, thereby forming an arrangement shown in FIG. 16.

Referring to FIG. 16, an embodiment is illustrated in which a hole CUH (e.g., see FIGS. 6 to 8) is formed to entirely extend in the second direction DR2 on the substrate SUB using the hole generator 1600. However, embodiments of the present disclosure are not limited thereto, and the hole CUH may be partially (or locally) formed in a partial area on the substrate SUB.

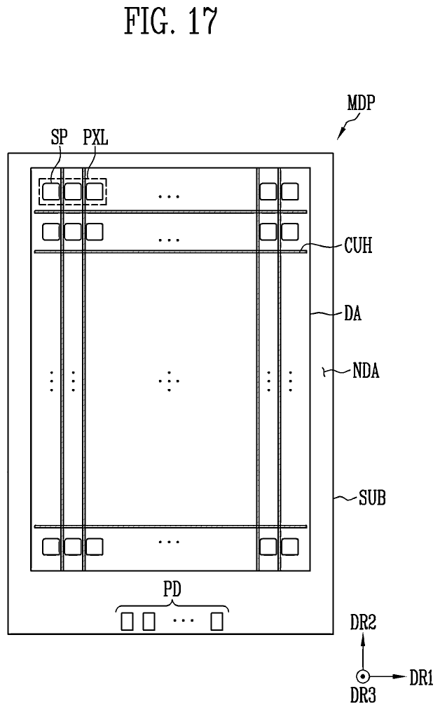

FIG. 17 is a plan view illustrating the display panel MDP in which holes CUH are formed. Each hole CUH may be formed between sub-pixels SP. In FIG. 17, some of the holes CUH may be formed between sub-pixels SP adjacent to each other in the first direction DR1. Other ones of the holes CUH may be formed between sub-pixels SP adjacent to each other in the second direction DR2.

Referring to FIG. 17, it is illustrated that the hole CUH is not formed at an outer portion of the display area DA. However, embodiments of the present disclosure are not limited thereto, and the hole CUH may further formed at the outer portion of the display area DA.

Referring to FIG. 17, a plurality of sub-pixels SP in the display panel MDP may be arranged side-by-side in the first direction DR1 and the second direction DR2 intersecting the first direction DR1. Some of the holes CUH may be located between a plurality of sub-pixels SP arranged side-by-side in the first direction DR1. Other ones of the holes CUH may be located between a plurality of sub-pixels SP arranged side by side in the second direction DR2.

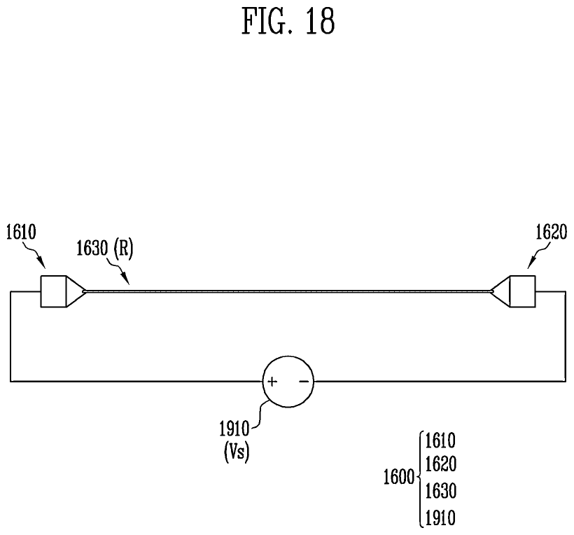

FIG. 18 is a system diagram of the hole generator 1600 in accordance with embodiments of the present disclosure.

Referring to FIG. 18, the hole generator 1600 in accordance with the embodiments of the present disclosure may include a first unit 1610, a second unit 1620, a wire 1630, and a voltage source 1910. The voltage source 1910 may be connected to the first unit 1610 and the second unit 1620. The voltage source 1910 may supply a high-potential voltage to one (e.g., the first unit 1610) of the first unit 1610 or the second unit 1620, and may supply a low-potential voltage to the other one (e.g., the second unit 1620) of the first unit 1610 or the second unit 1620. Accordingly, a potential difference (e.g., a predetermined voltage difference Vs) may be formed between the first unit 1610 and the second unit 1620.

The wire 1630 may have a resistance, e.g., a predetermined resistance R. Heat may be generated in the wire 1630 based on the potential difference Vs between ends of the wire 1630. The above-described hole CUH may be formed in the display panel MDP (e.g., see FIG. 17) by the heat generated in the wire 1630.

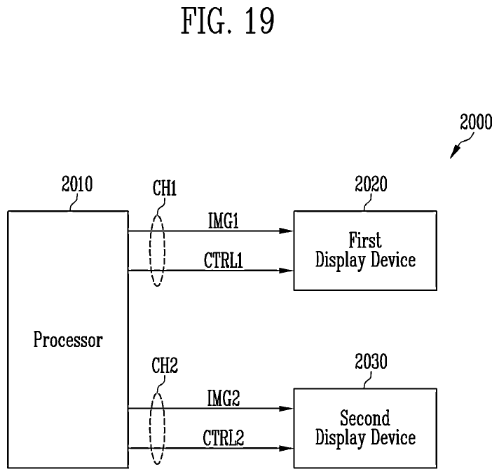

FIG. 19 is a diagram illustrating an embodiment of a display system 2000 in accordance with embodiments of the present disclosure.

Referring to FIG. 19, the display system 2000 may include a processor 2010 and one or more display devices 2020 and 2030. The processor 2010 may perform various tasks and various calculations. In embodiments, the processor 2010 may include an Application Processor (AP), a Graphics Processing Unit (GPU), a microprocessor, a Central Processing Unit (CPU), and the like. The processor 2010 may be connected to other components of the display system 2000 through a bus system to control the components of the display system 2000.

In FIG. 19, it is illustrated that the display system 2000 includes first and second display devices 2020 and 2030. The processor 2010 may be connected to the first display device 2020 through a first channel CH1, and be connected to the second display device 2030 through a second channel CH2.

Through the first channel CH1, the processor 2010 may transmit first image data IMG1 and a first control signal CTRL1 to the first display device 2020. The first display device 2020 may display an image based on the first image data IMG1 and the first control signal CTRL1. The first display device 2020 may be configured identically to the display device 100 described with reference to FIG. 1. The first image data IMG1 and the first control signal CTRL1 may be respectively provided as the image data IMG and the control signal CTRL, which are shown in FIG. 1.

Through the second channel CH2, the processor 2010 may transmit second image data IMG2 and a second control signal CTRL2 to the second display device 2030. The second display device 2030 may display an image based on the second image data IMG2 and the second control signal CTRL2. The second display device 2030 may be configured identically to the display device 100 described with reference to FIG. 1. The second image data IMG2 and the second control signal CTRL2 may be respectively provided as the image data IMG and the control signal CTRL, which are shown in FIG. 1.

The display system 2000 may include a computing system for providing an image display function. Examples include a portable computer, a mobile phone, a smartphone, a tablet personal computer (PC), a smart watch, a watch phone, a portable multimedia player (PMP), a navigation system, or an ultra mobile computer (UMPC). Also, the display system 2000 may include at least one of a head mounted display (HMD) device, a virtual reality (VR) device, a mixed reality (MR) device, and an augmented reality (AR) device.

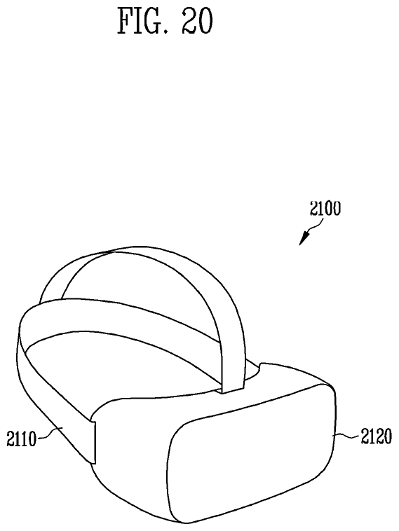

FIG. 20 is a perspective view illustrating an application example of the display system 2000 shown in FIG. 19.

Referring to FIG. 20, the display system 2000 shown in FIG. 19 may be applied to a head mounted display device 2100. The head mounted display device 2100 may be a wearable electronic device which can be worn on a head of a user.

The head mounted display device 2100 may include a head mounting band 2110 and a display device accommodating case 2120. The head mounting band 2110 may be connected to the display device accommodating case 2120. The head mounting band 2110 may include a horizontal band and/or a vertical band, used to fix the head mounted display device 2100 to the head of the user. The horizontal band may be configured to surround a side portion of the head of the user, and the vertical band may be configured to surround an upper portion of the head of the user. However, embodiments are not limited thereto. For example, the head mounting band 2110 may be implemented in the form of a glasses frame, a helmet or the like.

The display device accommodating case 2120 may accommodate the first and second display devices 2020 and 2030 shown in FIG. 19. The display device accommodating case 2120 may further accommodate the processor 2010 shown in FIG. 19.

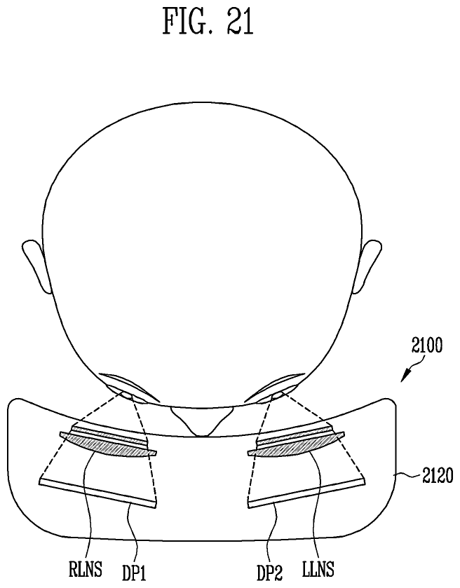

FIG. 21 is a view illustrating the head mounted display device 2100 worn by a user.

Referring to FIG. 21, a first display panel DP1 of the first display device 2020 (see FIG. 19) and a second display panel DP2 of the second display device 2030 (see FIG. 19) may be disposed in the head mounted display device 2100. The head mounted display device 2100 may further include one or more lenses. For example, the head mounted display device 2100 may include a left-eye lens LLNS and a right-eye lens RLNS.

In the display device accommodating case 2120, the right-eye lens RLNS may be disposed between the first display panel DP1 and a right eye of the user. In the display device accommodating case 2120, the left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. In the above embodiment, each of the first and second display panels DP1 and DP2 may output images corresponding to the sub-areas of the multi-channel lens, and the output images may be viewed by the user while respectively passing through corresponding sub-areas.

In the display panel and the manufacturing method thereof in accordance with the present disclosure influence of a leakage current between adjacent pixels, or adjacent sub-pixels of a pixel, can be reduced or prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A method of manufacturing a display panel, the method comprising:
forming, on a substrate, a pixel circuit layer including a sub-pixel circuit of each of a plurality of sub-pixels;
forming a first electrode of a light emitting element on the pixel circuit layer, wherein the first electrode of the light emitting element is electrically connected to the sub-pixel circuit;
forming a pixel defining layer on the first electrode of the light emitting element;
forming a light emitting structure of the light emitting element on the pixel defining layer;
forming a hole at a boundary area between adjacent ones of the plurality of sub-pixels, wherein the hole is formed using a wire of a hole generator; and
forming a second electrode of the light emitting element on the light emitting structure.

2. The method of claim 1, wherein forming the hole includes:
applying a high-potential voltage to a first end of the wire; and
applying a low-potential voltage to a second end of the wire.

3. The method of claim 1, wherein the plurality of sub-pixels are arranged side by side in a first direction and a second direction intersecting the first direction in the display panel, and
wherein forming the hole includes:
forming a first hole between the plurality of sub-pixels arranged side-by-side in the first direction; and
forming a second hole between the plurality of sub-pixels arranged side by side in the second direction.

4. The method of claim 1, wherein:
the light emitting structure includes a first light emitting area, a charge generation layer stacked in a third direction on the first light emitting area, and a second light emitting area stacked in the third direction on the charge generation layer, and
in the forming of the hole, the light emitting structure is removed to a predetermined depth by the wire.

5. The method of claim 4, wherein forming the hole includes sequentially removing the second light emitting area and the charge generation layer.

6. The method of claim 5, wherein forming the hole includes removing at least a portion of the first light emitting area.

7. The method of claim 6, wherein the hole is formed to expose the pixel defining layer.

8. The method of claim 6, wherein a width of the hole is less than a width of a top surface of the pixel defining layer.

9. The method of claim 5, wherein the hole is formed to expose at least a portion of the first light emitting area.

10. The method of claim 5, wherein a width of the hole is less than a width of a top surface of the pixel defining layer.

11. The method of claim 5, wherein a width of the hole is greater than a width of a top surface of the pixel defining layer.

12. The method of claim 11, wherein the hole and the first electrode of the light emitting element overlap each other in the third direction.

13. The method of claim 1, wherein the wire includes silver and has a width of 200 nm.

14. The method of claim 1, wherein forming the hole includes rotating one of the substrate or the hole generator by 90 degrees.

15. A display panel comprising:
a substrate having a plurality of sub-pixels disposed thereon;
a pixel circuit layer disposed on the substrate, the pixel circuit layer including a sub-pixel circuit of each of the plurality of sub-pixels; and
a light emitting element layer disposed on the pixel circuit layer, the light emitting element layer including a plurality of light emitting elements, each including a first electrode, a light emitting structure, and a second electrode, the light emitting element layer having a hole at least a portion of the light emitting structure in a boundary area between the plurality of sub-pixels.

16. The display panel of claim 15, wherein the hole corresponds to a width of a wire of a hole generator used to form the hole.

17. The display panel of claim 15, wherein:
the plurality of sub-pixels are arranged side-by-side in a first direction and a second direction intersecting the first direction, and
the hole is located between adjacent ones of the plurality of sub-pixels in the first direction and another hole is formed between adjacent ones of the plurality of sub-pixels arranged side-by-side in the second direction.

18. The display panel of claim 15, wherein the light emitting structure includes:
a first light emitting unit including a first light emitting layer;
a charge generation layer stacked in a third direction on the first light emitting unit; and
a second light emitting unit including a second light emitting layer, the second light emitting unit being stacked in the third direction on the charge generation layer, and
wherein the hole is located in an area in which the second light emitting unit and the charge generation layer are removed.

19. The display panel of claim 18, wherein the hole is located in an area in which the first light emitting unit is further removed.

20. The display panel of claim 18, wherein the hole and the first electrode of the light emitting element overlap with each other in the third direction.

21. A display panel, comprising:
a first sub-pixel including a first electrode;
a second sub-pixel including a second electrode adjacent to the first electrode; and
a light emitting structure disposed on the first electrode and the second electrode, wherein the light emitting structure includes a hole disposed at a location between the first sub-pixel and the second sub-pixel, the hole extending to a depth that removes a charge generation layer between a stacked arrangement of different light emitting areas of at least one of the first sub-pixel and the second sub-pixel.

22. The display panel of claim 21, further comprising:
a pixel defining layer commonly included in the first sub-pixel and the second sub-pixel.

23. The display panel of claim 22, wherein the depth of the hole is less than a distance between a top surface of the first electrode and a top surface of the light emitting structure.

24. The display panel of claim 22, wherein the hole overlaps the pixel defining layer.

25. The display panel of claim 21, wherein the hole has a width that is less than a width between the first electrode and the second electrode.

26. The display panel of claim 21, wherein the hole has a width that is less than a width between the first electrode and the second electrode.

27. The display panel of claim 21, wherein the hole has a width greater than a width between the first electrode and the second electrode.

28. The display panel of claim 27, wherein the hole overlaps respective portions of the first electrode and the second electrode.

29. The display panel of claim 27, wherein the depth of the hole is less than a distance between a top surface of the first electrode and a top surface of the light emitting structure.
